(19) United States
(12) Patent Application Publication
(10) Pub. No.: US 2005/0017337 A1
(43) Pub. Date: Jan. 27, 2005

(54) Stacking apparatus for integrated circuit assembly

(76) Inventor: Cherng-Chiao Wu, Taichung City (TW)

Correspondence Address: BIRCH STEWART KOLASCH & BIRCH, PO BOX 747, FALLS CHURCH, VA, 22040-0747, US

(21) Appl. No.: 10/622,461

(22) Filed: Jul. 21, 2003

(51) Int. Cl. H01L 23/02

(52) U.S. Cl. 257/686

(57) ABSTRACT

An apparatus for stacking a plurality of integrated circuit assemblies includes a connection substrate for soldering the integrated circuit assemblies. The substrate has a carved out frame structure or a cavity in the center that has a dimension matching the integrated circuit assemblies. There are solder spots or through holes located on the periphery of the frame structure or cavity. The solder spots may be located on one side or two sides of the substrate. The one side solder spots are electrically connected to other substrate surface through leads or conductive through holes. The integrated circuit assemblies are sunken in the frame structure or cavity. The legs of the assemblies are connected to the solder spots. Thus the assemblies are stacked over one another in a layer fashion to form a final assembly package.

### BACKGROUND OF THE INVENTION

1. Field of the Invention

The invention relates to an apparatus for stacking integrated circuit (IC) assembly that has a substrate with an opening or cavity of a matching dimension formed in the center for holding the assembly in a sunken manner and solder spots located on the periphery of the opening or cavity, and the upper and lower solder spots are connected electrically to enable the legs of the assembly to be soldered to the solder spots of the substrate.

2. Description of the Prior Art

The performance of electronic products usually is determined by the capacity and processing efficiency of their internal elements. For instance, the capacity of memory affects the processing efficiency of the electronic products. Memory, either the dynamic random access memory (DRAM) or static random access memory (SRAM), mostly is formed in a modular fashion. A plurality of memories are laid and mounted onto a printed circuit board (PCB) in an array manner to form a memory module. It is well known that the dimension of the memory module has a standard specification. Hence the module of a selected dimension can hold only a selected number of memory chips to form a module of a selected memory capacity. When to expand the memory capacity, increasing the number of memory is the simplest way. However, such an approach must increase the dimension of the module. It is not acceptable in the current trend that demands slim and light for information products. It also is against the common specifications. To remedy this problem, a method has been developed to expand the memory capacity without increasing the dimension of the module. It is accomplished by stacking the individual memory within the allowable height limit so that the memory capacity may be increased many times. However, such a method also has problems. Referring to FIG. 1, at present the package of chips mostly employs Lead Frame Package. The IC assembly made by such a method has fine and exposed legs. When the memory made by such packaging method is stacked, the legs 11 of the upper layer assembly 10 have to be extended longer to connect to legs 13 of the lower assembly 12 on the surface of the PCB 2. Such a practice tends to break the legs and results in poorer yields because of the fine and longer legs are difficult to fabricate. Moreover, the upper and lower assemblies 10 and 12 have different lengths of legs, and different molds must be used for production. Fabrication cost is higher. The extended legs also have poorer electric properties.

### SUMMARY OF THE INVENTION

The object of the invention is to provide a novel stacking apparatus for IC assembly to eliminate the shortcomings occurred to the conventional stacking methods. The invention employs a stacking technique developed in the Chip Scale Package (CSP) technology for packaging the assembly. Referring to FIG. 2, the CSP assembly 3 has a shorter leg 31. The invention aims at providing an apparatus for stacking CSP assembly. It includes a substrate that has an opening or cavity in the center that has a dimension matching a CSP assembly. The opening or cavity has periphery which has solder spots or through holes. Then the solder spots are connected to another substrate surface which does not have solder spots through leads or conductive through holes to establish electric connection between the solder spots and an external object, or between the upper and lower surfaces of the substrate through the through holes. The CSP assembly is held and sunk in the opening or cavity with the legs soldered on the solder spots of the substrate, and then the solder spots are connected electrically to the outside. The CSP assembly may be stacked one over the other by soldering the legs together, or by soldering another substrate on the CSP assembly and soldering another assembly on the substrate. By means of the aforesaid structure, the substrate may serve as a stacking package interface between the CSP assemblies to achieve a secured structure to avoid leg breaking caused by extension of the legs during stacking assemblies in the conventional lead frame package. In addition, regardless of the layer number of the assembly, each assembly may be connected through the substrate and soldered to the circuit board. The legs have the same length and may result in improved electric properties. Moreover, the structure of the substrate is simpler, and fabrication cost is lower than the conventional stacking methods. It may be fabricated in a mass production fashion to increase the capacity of memory modules.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a stacking structure of a conventional lead frame package chip.

FIG. 2 is a schematic view of the structure of a conventional CSP chip.

FIG. 3 is a perspective view of the substrate of the invention with an opening.

FIG. 4 is a schematic view of the invention showing the substrate bonding to a PCB.

FIG. 5 is a perspective view of the substrate of the invention with a cavity.

FIGS. 6, 7, 8 and 10 are schematic views of the invention showing various structures for stacking CSP chip.

FIG. 9 is a schematic view of the invention in use with the substrate having an air vent.

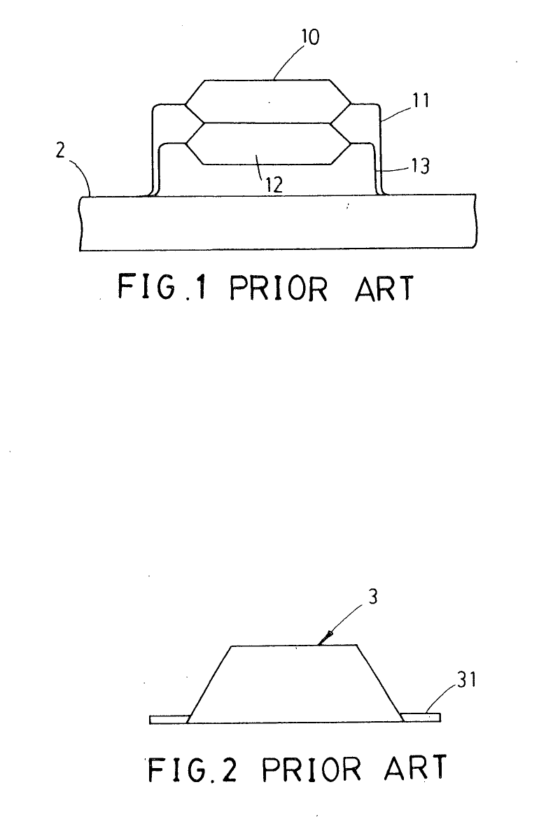

### DESCRIPTION OF THE PREFERRED EMBODIMENTS

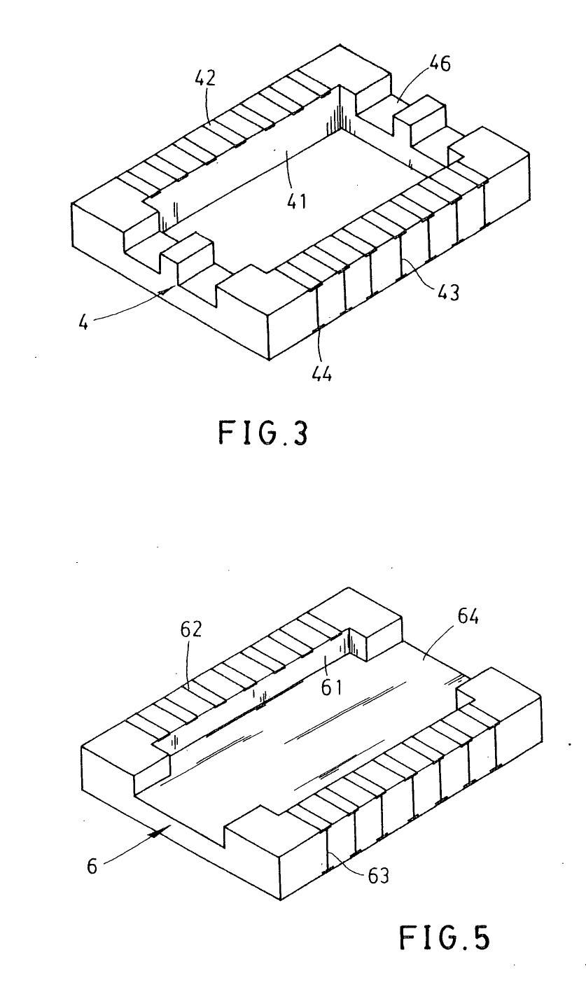

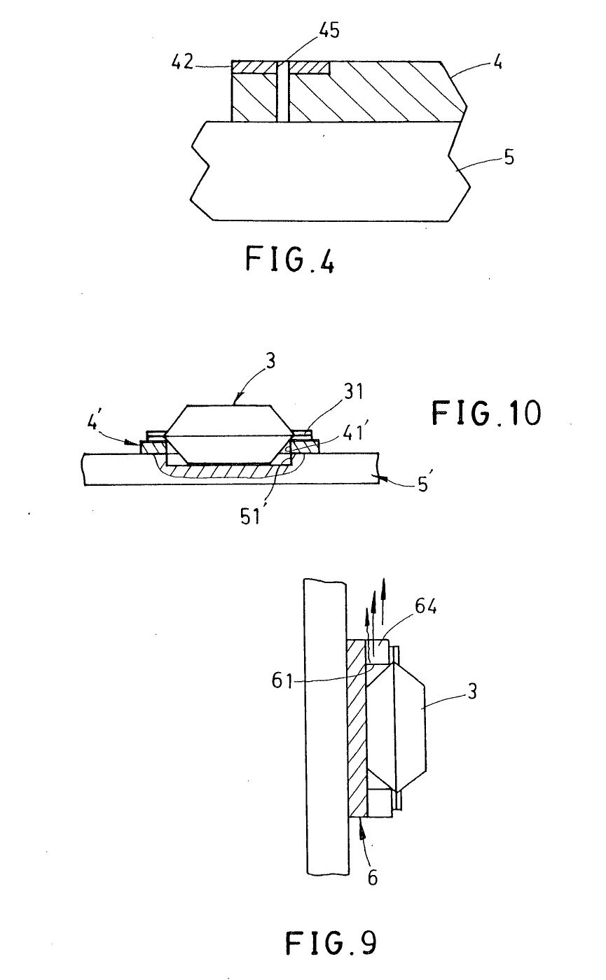

Refer to FIG. 3 for a preferred embodiment of the invention. The invention includes a substrate 4 that has an opening 41 in the center and a plurality of solder spots 42 located on the periphery of the opening 41. The solder spots 42 on a upper layer are connected to solder spots 44 on a lower layer through leads 43. Or as shown in FIG. 4, conductive through holes 45 which has a inner wall plated with a conductive metal layer may also be formed to replace the leads 43 to connect the upper and lower solder spots 42 and 44. In another aspect, the solder spots may be formed only on the upper side of the substrate 4 and with the leads 43 or conductive through holes 45 connecting to the bottom side of the substrate 4, then circuits on the PCB 5 are connected to the leads 43 or conductive through holes 45. Referring to FIG. 5 for another preferred embodiment of the invention. The substrate 6 has a cavity 61 in the center and a plurality of solder spots 62 linking by leads 63 or conductive through holes located on the periphery (not shown in the drawing) to establish electric connection with the upper and lower sides of the substrate.

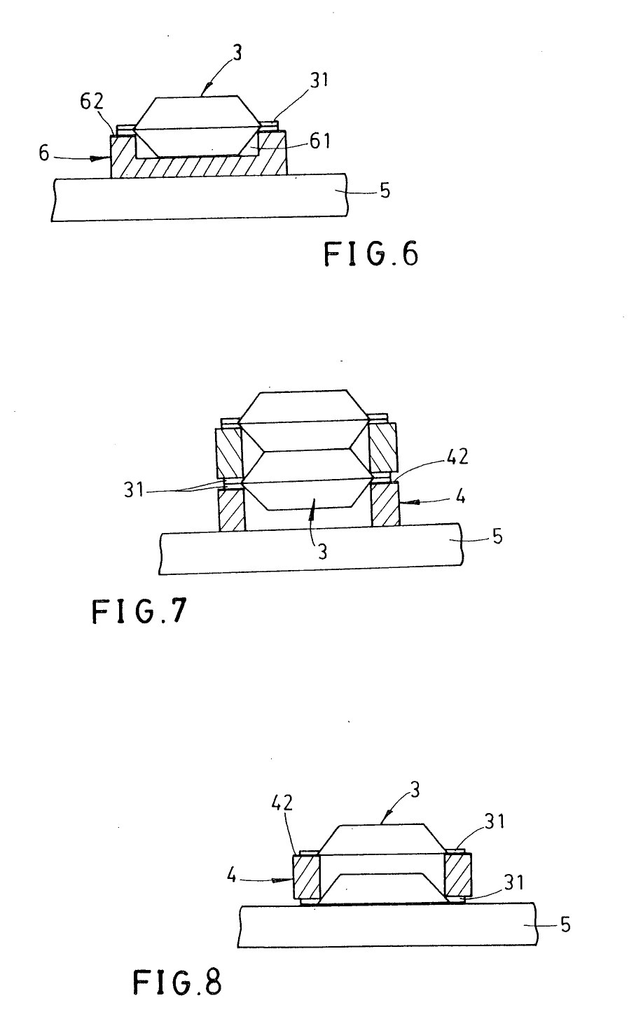

Referring to FIGS. 6, 7 and 8, the opening 41 or cavity 61 is to hold a CSP assembly 3, thus it has a dimension matching or larger than the CSP assembly 3. Stacking of the CSP assembly 3 may be accomplished in a number of ways as follows:

Referring to FIG. 6, the CSP assembly 3 is soldered on the corresponding legs 31, then with one bonded CSP assembly 3 disposed and sunk in a cavity 62 of a cavity type substrate 6 or in an opening 41 of an opening type substrate 4 (as shown in FIG. 7). The sunken CSP assembly 3 is connected to the solder spots 42 and 62 of substrates 4 and 6 through legs 31. Finally, the substrates 4 and 6 are soldered to the PCB 5. The upper CSP assembly 3 may further be covered by an opening type substrate 4, with the leads 43 of the substrate 4 or conductive through holes 45 soldering on the legs 31 of the upper CSP assembly 3. Thereby a plurality of CSP assemblies 3 may be stacked upwards on the substrate 4. Referring to FIG. 8 for another embodiment of the invention. The CSP assembly 3 has legs 31 directly soldering on the surface of the PCB 5, then an opening type substrate 4 is framed on the periphery of the CSP assembly 3 and the conductive bottom portion of the substrate 4 is connected to the legs 31 of the chip. Therefore, a plurality of CSP assemblies 3 and the substrate 4 may be coupled to form stacking layers to obtain the stacking IC assembly. Referring to FIG. 10 for yet another embodiment of the invention, two CSP assemblies 3 are soldered on the corresponding legs 31. One of the CSP assemblies 3 is sunk in an opening 41′ of an opening type substrate 4′ and a cavity 51′ of a PCB 5′. Such a structure can effectively reduce the upward height of the package that contains a plurality of CSP assemblies 3.

As the invention produces IC assembly by stacking, in order to enable the finished product to have a long operation durability, working temperature of the stacked assembly must be resolved properly. To meet this end, the substrates 4 and 6 may have air vents 46 and 64 on one side leading to the opening 41 or cavity 61. Then heat generated by the assembly 3 may be dispersed to increase the service life of the assembly (referring to FIGS. 3, 5 and 9).

While the preferred embodiments of the invention have been set forth for the purpose of disclosure, modifications of the disclosed embodiments of the invention as well as other embodiment thereof may occur to those skilled in the art. For instance, the solder spots on the substrate may be substituted by conductive through holes. Accordingly, the appended claims are intended to cover all embodiments which do not depart from the spirit and scope of the invention.

1. A stacking apparatus for integrated circuit assemblies comprising at least one substrate and one integrated circuit assembly stacking over each other, wherein:
the substrate has an opening in the center of a upper surface of the substrate and a plurality of solder spots located on the periphery of the opening, the solder spots being electrically connected to lower surface of the substrate; and
the integrated circuit assembly sunk in the aforementioned opening, with its legs soldering on the solder spots of the substrate, combining the substrate to make a unit structure; two or more such units can be stacked and soldered over each other, with their bottom soldering to a surface of a printed circuit board.

2. The stacking apparatus of claim 1, wherein the opening in the center of the substrate is a through hole running through an upper surface and a lower surface of the substrate.

3. The stacking apparatus of claim 1, wherein the opening in the center of the substrate is a cavity sunk from a surface of the substrate.

4. The stacking apparatus of claim 2, wherein the periphery of the opening has solder spots located on the upper surface and the lower surface of the substrate; the solder spots on the upper surface and the lower surface are connected electrically.

5. The stacking apparatus of claim 3, wherein the periphery of the cavity has solder spots that are electrically connected to the other surface of the substrate.

6. The stacking apparatus of claim 5, wherein the solder spots on the periphery of the cavity of the substrate are electrically connected to the surface of the printed circuit board.

7. The stacking apparatus of claim 1, wherein the substrate has a lateral side that has air vents communicating with the opening in the center thereof.

8. The stacking apparatus of claim 1, wherein the units are soldered and coupled through corresponding legs located on an upper layer unit and a lower layer unit, the substrate of the lower layer unit has a bottom side bonding to the printed circuit board to form stacking.

9. The stacking apparatus of claim 1, wherein the units include a lower layer unit which has legs soldering on the printed circuit board, and an upper layer unit which has legs bonding to solder spots located on an upper surface of a substrate of the lower layer unit to form stacking.

10. The stacking apparatus of claim 1, wherein a portion of bottom of the lower unit sinks into the cavity of the surface of the printed circuit board.
